(19) United States
(12) Patent Application Publication
(10) Pub. No.: US 2016/0226480 A1
(43) Pub. Date: Aug. 4, 2016

(54) Modular Multipoint Power Converter for High Voltages

(71) Applicant: SIEMENS AKTIENGESELLSCHAFT, München (DE)

(72) Inventor: Rainer MARQUARDT, Ottobrunn/Riemerling (DE)

(21) Appl. No.: 15/021,353

(22) PCT Filed: Jul. 15, 2014
(86) PCT No.: PCT/EP2014/065069

§ 371 Date: Mar. 11, 2016

(30) Foreign Application Priority Data
Sep. 11, 2013 (DE) 10 2013 218 207.4

(51) Int. Cl. H03K 17/60; H02M 1/12; H02M 7/00

(52) U.S. Cl. CPC H03K 17/603; H02M 7/003; H02M 1/12

(57) ABSTRACT

A sub module for a converter has first and second subunits. Each subunit has an energy storage device, a first series circuit with two power semiconductor switching units, each with a power semiconductor which can be switched on and off, which have the same forward direction and which are conductive in the direction opposite the forward direction. The first series circuit is connected in parallel with the energy storage device. A connection terminal is connected to the potential node between the power semiconductor switching units in the respective series circuit. The first and second subunits are connected via an emitter connection branch, a collector connection branch, and a switching branch with a switching unit connected between the emitter and collector connection branches. At least one power semiconductor switching unit is arranged in the emitter connection branch or the collector connection branch.

The invention relates to a two-pole sub module for constructing a converter. Said sub module here comprises a first subunit that comprises a first energy store, a first series circuit connected in parallel with the first energy store, said series circuit having two power semiconductor switching units, each of which comprises a power semiconductor that can be switched on and off and having the same forward conduction directions, and each of which is capable of conducting in a direction opposite to said forward conduction direction, and a first connecting terminal which is connected to the potential node between the power semiconductor switching units of the first series circuit. The sub module furthermore comprises a second subunit that comprises a second energy store, a second series circuit connected in parallel with the second energy store, said series circuit having two power semiconductor switching units, each of which comprises a power semiconductor that can be switched on and off and having the same forward conduction directions, and each of which is capable of conducting in a direction opposite to said forward conduction direction, and a second connecting terminal which is connected to the potential node between the power semiconductor switching units of the second series circuit. The first subunit and the second subunit are, moreover, connected to one another via connecting means. Said connecting means comprise an emitter connecting branch that connects an emitter of a first power semiconductor switching unit of the first series circuit to an emitter of a first power semiconductor switching unit of the second series circuit, a collector connecting branch that connects a collector of the second power semiconductor switching unit of the first series circuit to a collector of the second power semiconductor switching unit of the second series circuit, and a switching branch in which a switching unit is arranged and which connects the emitter connecting branch to the collector connecting branch.

The invention relates furthermore to a converter with a series circuit of such two-pole sub modules, wherein the series circuit of the sub modules is arranged between an AC voltage terminal and a DC voltage terminal of the converter.

The use of power electronic systems in the field of very high voltages and powers has become increasingly important. The power electronic systems are primarily used for controlling the flow of energy between various energy supply networks (network couplings, high voltage direct current transmission (HVDC)). In particular for spatially extended, branched high voltage direct current networks to which several converters are connected (“multi-terminal”), the secure and fast handling of possible faults can be of crucial significance.

In the past, primarily power converters with thyristors and impressed direct current have been employed for the very high powers that are required. These, however, do not satisfy the requirements, rising in the future, for highly dynamic reactive power compensation, network voltage stabilization, favorable usability of DC voltage cables and the ability to realize branched HVDC networks. Power converters with impressed DC voltage are therefore primarily developed as the preferred type of circuitry. This type of power converter is also known as a voltage source converter (VSC). A disadvantage of some of the usual voltage source converters is in particular that, in the event of a short-circuit on the DC voltage side of the converter, extremely high discharge currents flow from the capacitor bank on the DC voltage side, which can cause destruction as a result of the action of extremely high mechanical forces and/or the effect of arcs.

This disadvantage of known voltage source converters is a topic of document DE 10 103 031 A1. The converter described there comprises power semiconductor valves connected to one another in a bridge circuit. Each of these power semiconductor valves has an AC voltage terminal and a DC voltage terminal, and consists of a series circuit of two-pole sub modules, each of which comprises a unipolar storage capacitor and a power semiconductor circuit connected in parallel with the storage capacitor. The power semiconductor circuit consists of a series circuit of power semiconductor switches oriented in the same sense, such as IGBTs or GTOs, each of which has a freewheeling diode of the opposite polarity connected in parallel with it. One of two connecting terminals of one of these sub modules is connected to the storage capacitor, and the other connecting terminal is connected to the potential node between the two power semiconductor switches that are capable of being switched on and off. Depending on the switching state of the two actuable power semiconductors, either the capacitor voltage, present at the storage capacitor or a zero voltage can be generated at the two output terminals of the sub module. As a result of the series circuit of the sub modules within the power semiconductor valve, what is known as a DC voltage impressing multi-stage converter is provided, wherein the height of the voltage stages is determined by the height of the respective capacitor voltage. Multi-stage or multi-point converters of this sort have the advantage over the two-stage or three-stage converters with central capacitor banks that high discharge currents are avoided in the event of a short-circuit on the DC voltage side of the converter. In addition to this, the expense required to filter upper harmonics of multi-stage converters is less than that required for two-point or three-point converters.

Appropriate topologies are meanwhile employed industrially for HVDC. One of the advantages of this topology—as is known from the document cited above—lies in its strictly modular design.

However, in particular for constructing spatially extended, branched HVDC networks, the secure and fast handling of possible faults in the HVDC network has not been satisfactorily solved. Corresponding, spatially extended, branched HVDC networks will in future be required, amongst other things, for large offshore wind farms and for the use of large solar power stations in remote desert regions. It must in particular be possible to handle short-circuits in the HVDC network.

Favorable mechanical switches for the extremely high DC voltages, able to switch high fault currents under load, are not available due to fundamental physical problems. The technically achievable switch-off times and the switching over-voltages of mechanical switches are also troublesome. In accordance with the prior art, therefore, mechanical switches for these applications can only be realized favorably as zero-load (zero-current) isolators.

A direct substitution of mechanical power switches by electronic DC power switches in the high-voltage field is extremely expensive. The additional conduction losses of the semiconductors also speak against it. For this reason, what are known as hybrid HVDC switches have been developed and publicized, containing additional mechanical switches for the purpose of avoiding and/or reducing the conduction losses. This measure, however, again impairs the achievable switch-off times due to the mechanical switches.

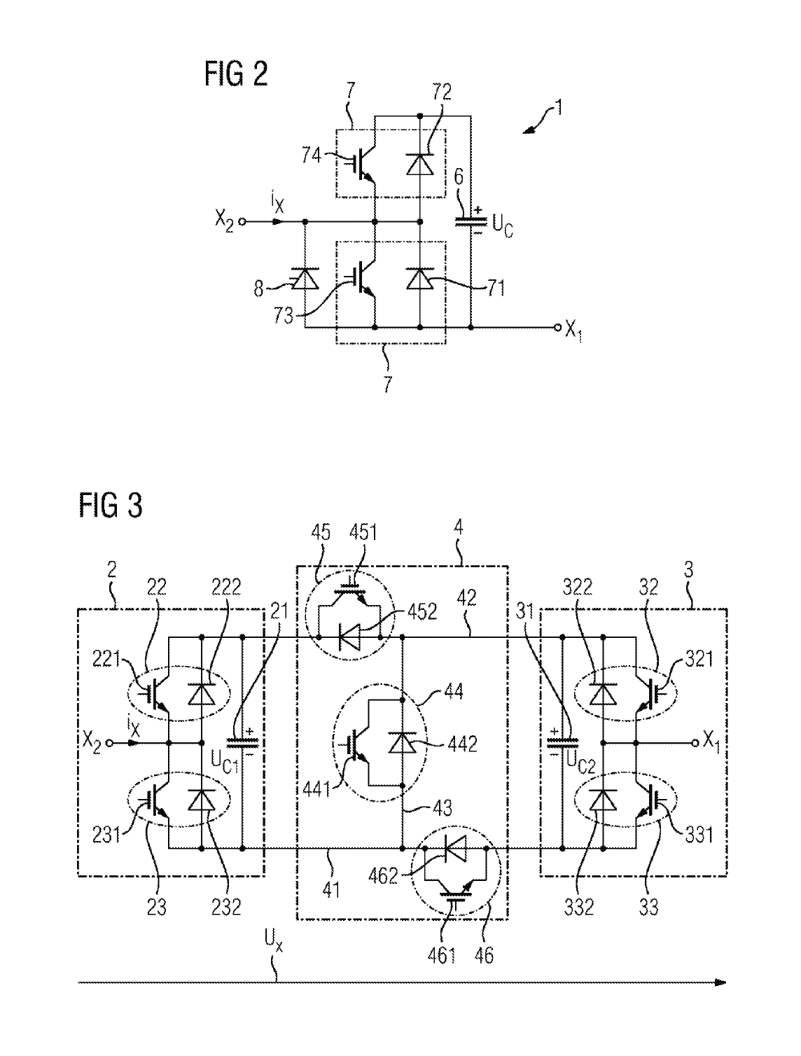

FIG. 2 shows a schematic illustration of an example of the interior circuitry of a sub module as is known from the prior art. The sub module 1 illustrated in FIG. 2 differs from the embodiment known from DE 10 103 031 A1 in that it has an additional thyristor 8. In the event of a fault, this has the purpose of relieving the parallel freewheeling diode 71 of unacceptably high current surges. For this purpose, the thyristor 8 must be triggered in the event of a fault. The sub module 1 of FIG. 2 contains, as further components, two controllable electronic switches 73, 74 in a known arrangement, consisting of IGBTs with a high reverse voltage, associated anti-parallel freewheeling diodes 71, 72, and an energy store 6, which is embodied as a unipolar storage capacitor.

When the terminal current ix has a polarity opposite to the technical current direction drawn in FIG. 2, the sub module 1 of FIG. 2 cannot absorb any energy, regardless of the actuated switching state. This fact is very disadvantageous in the event of a fault. This applies in general for the population with sub modules that can only generate one polarity of the terminal voltage Ux.

The use of what are known as H-bridges (full bridges) as sub modules is obvious to the expert—and is known from a variety of publications (see, for example, the document DE 102 17 889 A1). These can generate an appropriate opposing voltage for any polarity of the terminal current, i.e. can absorb energy. This offers the following advantages:
the currents on the DC side and on the three-phase side can be electronically switched off and/or limited by the converter itself in the event of network faults—in particular in the event of short-circuits in the DC network.
the achievable switch-off times are short in comparison with the switch-off times of mechanical switches or of hybrid HVDC switches
a higher AC voltage can be achieved in normal operation, so allowing a design with a somewhat higher secondary voltage in the network transformer (and consequently a smaller AC current). This is a valuable degree of freedom of the dimensioning.

However, the fact that the conduction power loss of the sub modules at the same current is doubled is extremely disadvantageous. This is of considerable commercial significance, in particular in the energy supply field, as a result of the continuous operation at high powers. In terms of functionality during normal operation, however, the new degree of freedom of dimensioning for smaller AC currents is valuable.

A converter with the generic sub module is known from document DE 10 2008 057 288 A1. A potential isolation diode as well as, optionally, a damping resistor, are arranged there in each case in the emitter connecting branch and in the collector connecting branch of the connecting means. The potential isolation diodes are arranged such that the switching branch of the connecting means connects a cathode of the potential isolation diode of the emitter connecting branch to an anode of the potential isolation diode of the collector connecting branch. Through the design of the connecting means, it is possible to achieve, with suitable actuation of the power semiconductor switching units, that a flow of current between the two connecting terminals of the sub module must always take place by way of at least one energy store. Regardless of the polarization of the terminal current, the energy store concerned in each case always develops an opposing voltage that allows the flow of current to decay more quickly. It has been found to be disadvantageous with this solution that negative terminal voltages cannot be generated for both polarities of the terminal current ix. As a result, the additional degree of freedom of dimensioning for smaller AC currents cannot be realized. This disadvantage is also exhibited by the known arrangement of a converter with an HVDC switch immediately following on the DC side of the converter.

There therefore continues to be a high demand for a technically more favorable realization of the sub modules than is possible with cascaded full bridges.

The object of the present invention is to propose a sub module and a converter of the type mentioned at the outset in which the semiconductor power loss of the sub modules in normal operation is reduced, the number of controllable semiconductor switches is limited, and a uniform population of the sub modules with semiconductors is permitted.

On the basis of the sub module mentioned at the outset, the invention achieves the object in that at least one power semiconductor switching unit is arranged in the emitter connecting branch or the collector connecting branch of the connecting means of the sub module according to the invention.

On the basis of the converter mentioned at the outset, the invention achieves the object in that each sub module of the converter according to the invention is a sub module according to the present invention.

Advantageously, the sub module according to the invention permits the desired handling of faults, and in normal operation replaces a series circuit of two full bridges through the possibility of generating negative terminal voltages of the sub module.

Depending on the configuration of the invention, the relevant improvements are as follows:
a reduction in the total semiconductor power loss of the sub modules in normal operation.
a limit on the number of controllable semiconductor switches (including IGBTs) and of the total semiconductor area.
retention of the possibility of populating the sub module with semiconductors of uniform reverse voltage and structure.

The first two points represent a significant advance in comparison with the known use of cascaded full bridges. The last point is equivalent to the use of full bridges. Its significance arises in that only a few semiconductor switches are suitable for the extremely high voltages and powers. At present, these are IGBT transistors with a high reverse voltage, or IGCTs, and in future will also include SiC semiconductors. A uniform population makes it possible to employ only those semiconductors that are most suitable and of the highest performance in each case.

The power semiconductor switching units can be realized as semiconductor switches each with associated antiparallel diodes, or as reverse-conducting semiconductor switches. The required reverse voltage of all the power semiconductor switching units is oriented to the maximum voltage of the energy stores which take the form, for example, of unipolar storage capacitors. Preferably, the reverse voltage is the same for all the power semiconductor switching units.

The invention in particular includes a configuration of the sub module in which at least one power semiconductor switching unit is arranged in the emitter connecting branch and at least one potential isolation diode is arranged in the collector connecting branch.

An embodiment is accordingly also possible in which the at least one potential isolation diode is arranged in the emitter connecting branch and the at least one power semiconductor switch is arranged in the collector connecting branch.

The at least one potential isolation diode here serves to maintain a voltage difference between the first and second subunits of the sub module.

According to a preferred embodiment of the invention, at least one power semiconductor switching unit is provided both in the emitter connecting branch and at least one also in the collector connecting branch of the connecting means. This embodiment has the advantage that negative voltages can be generated at the connecting terminals of the sub module, corresponding to the voltages of the energy stores of the subunits.

The switching branch can, for example, connect an emitter of the power semiconductor switching unit of the connecting means arranged in the collector connecting branch to a collector of the power semiconductor switching unit of the connecting means arranged in the emitter connecting branch.

The switching unit of the switching branch can be realized as a mechanical switching unit, as a semiconductor switch or as a power semiconductor switching unit.

According to an exemplary embodiment of the invention, the switching unit in the switching branch of the connecting means is a power semiconductor switching unit. The emitter of the power semiconductor switching unit arranged in the collector connecting branch is connected to the collector of the power semiconductor switching unit of the switching branch, and the emitter of the power semiconductor switching unit of the switching branch is connected to the collector of the power semiconductor switching unit arranged in the emitter connecting branch.

In any case, it is advantageous for the switching unit to be selected such that the power loss arising in it during normal operation of the sub module is as low as possible.

Depending on the topology of the sub module, a switching state of the power semiconductor switching units of the sub module can be defined in which the sub module absorbs energy regardless of the current direction. Preferably, the sub module absorbs energy regardless of the current direction in a switching state in which all the power semiconductor switching units are in their interrupting state. If, accordingly, all the power semiconductor switching units are placed into their interrupting state, the sub module can advantageously develop an opposing voltage for decay of the current in the event of a fault, regardless of the current direction. According to the invention, this allows a high short-circuit current to be handled without additional external switches. It is ensured in the context of the invention that high short-circuit currents can be avoided quickly, reliably and effectively in both directions by the converter itself. Additional switches, for example in the DC voltage circuit that is connected to the converter, or else semiconductor switches connected in parallel to a power semiconductor of the sub module, are superfluous in the context of the invention. In the event of a fault, the sub modules absorb the energy released almost exclusively, so that this is fully absorbed. The absorption of energy has an opposing voltage as a result, and can be measured in a defined manner through the dimensioning of the capacitors. Unfavorably high voltages can be avoided through this. In addition, the controlled charging of an energy store is not necessary to restart the converter. The converter according to the invention is, rather, able to restart its normal operation at any time following an electronic switch-off.

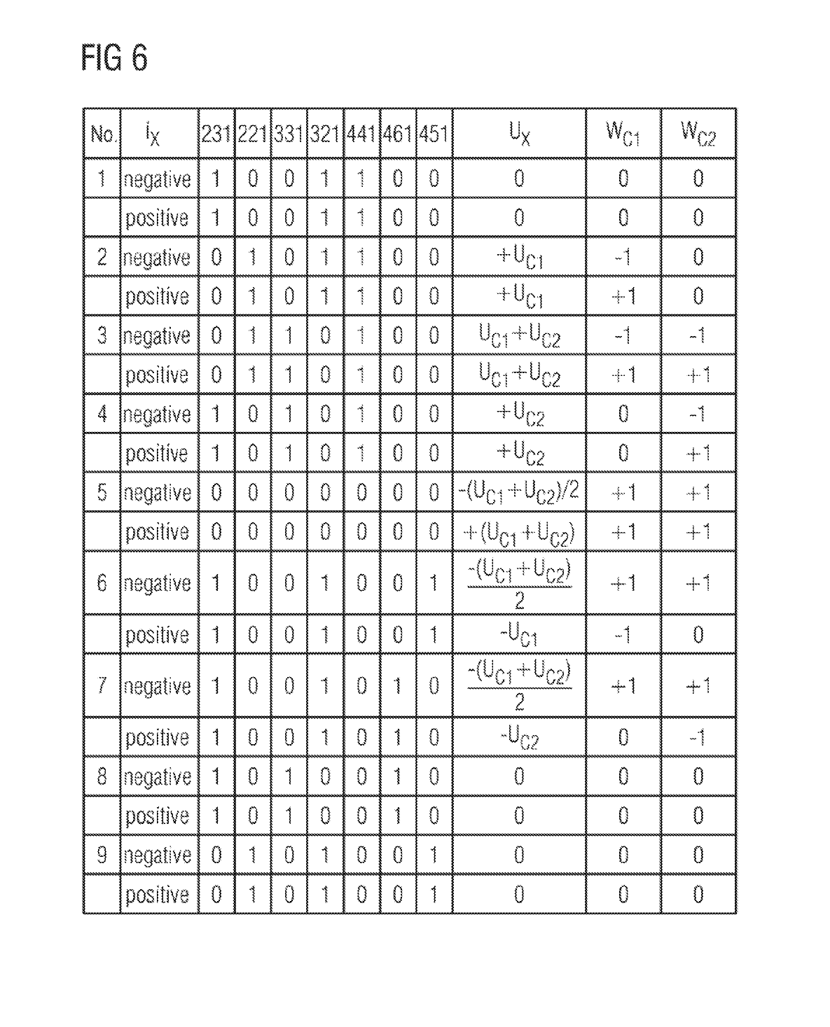

Further usable switching states that generate opposing voltage are given in association with the exemplary embodiment illustrated in FIG. 6. Each of these is highlighted in that one or both of the arithmetic signs (cf. Wc1, Wc2 in FIG. 6) is/are positive, so indicating energy absorption of the energy stores concerned.

Preferably, the power semiconductor switching units are reverse-conducting power semiconductor switches that can be switched on and off.

The power semiconductor switching units can each also comprise a power semiconductor that can be switched on and off, with which a freewheeling diode is connected in parallel but with the opposite polarity.

According to one exemplary embodiment of the invention, each energy store of the sub module is a unipolar storage capacitor.

According to a further embodiment of the invention, the connecting means comprise a second switching branch that connects the emitter switching branch to the collector switching branch, and in which a power semiconductor switching unit is arranged. The power semiconductor switching unit arranged in the first switching branch is here connected in parallel with the power semiconductor switching unit arranged in the second switching branch. This embodiment yields the advantage of a reduced conduction power loss. In addition, connecting lines arranged between the subunits are not critical in terms of their length and stray inductance. This allows both of the partial units of the sub module that are connected to one another by the connecting lines to be structurally and spatially separate, so giving rise to significant advantages for the industrial series production and for servicing.

Embodiments of the sub modules according to the invention that replace three or more cascaded full bridges can in principle also be realized. The connecting means can be fitted with three or more switching branches for this purpose, in which further power semiconductor switching units, energy stores or other components can be arranged. Under some circumstances, however, the relative advantages of such embodiments can wane in comparison with the embodiments described above.

It can be established that the conduction power loss can be reduced in comparison with cascaded full bridges in general by a factor of between 0.5 and 0.8, depending on the embodiment of the sub module and depending on the characteristic semiconductor conduction curve.

This is explained with reference to the following exemplary characteristic conduction curves. If all the power semiconductors exhibit a purely ohmic characteristic conduction curve in both current directions—as would be the case with appropriately actuated field effect transistors—then the following conduction power loss would apply for two conventional, cascaded full bridges:

P_{P}=(I_{XRMS})²·4·R₀

where I_{XRMS} represents the effective value of the branch current, and R₀ represents the conduction resistance per power semiconductor. The following applies to the exemplary embodiment according to FIG. 3:

P_{P}′=(I_{XRMS})²·3R₀

wherein the required semiconductor area is additionally reduced to ⅞. With an equal total semiconductor area, the conduction resistance per power semiconductor can be reduced to R₀′=⅞·R₀, so that the power loss is even smaller.

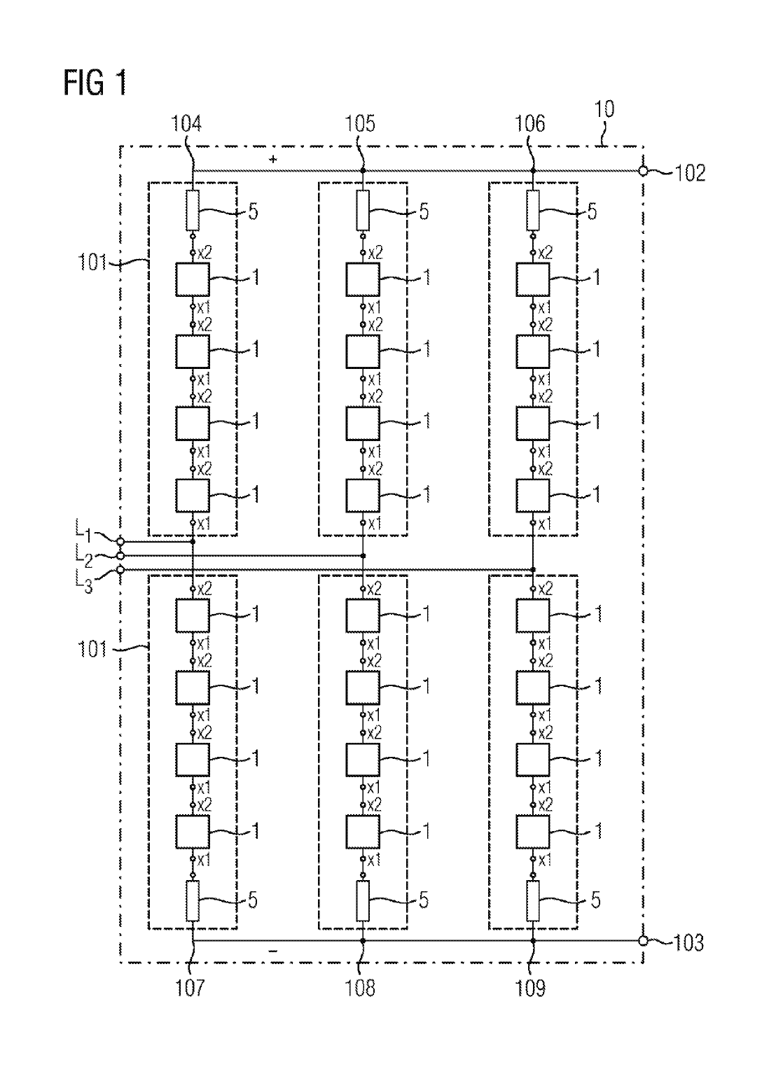

The invention is explained in more detail below with reference to FIGS. 1 to 6.

FIG. 1 shows a schematic representation of an exemplary embodiment of a multi-stage converter;

FIG. 2 shows a sub module from the prior art;

FIG. 3 shows a schematic representation of a first exemplary embodiment of a sub module according to the invention;

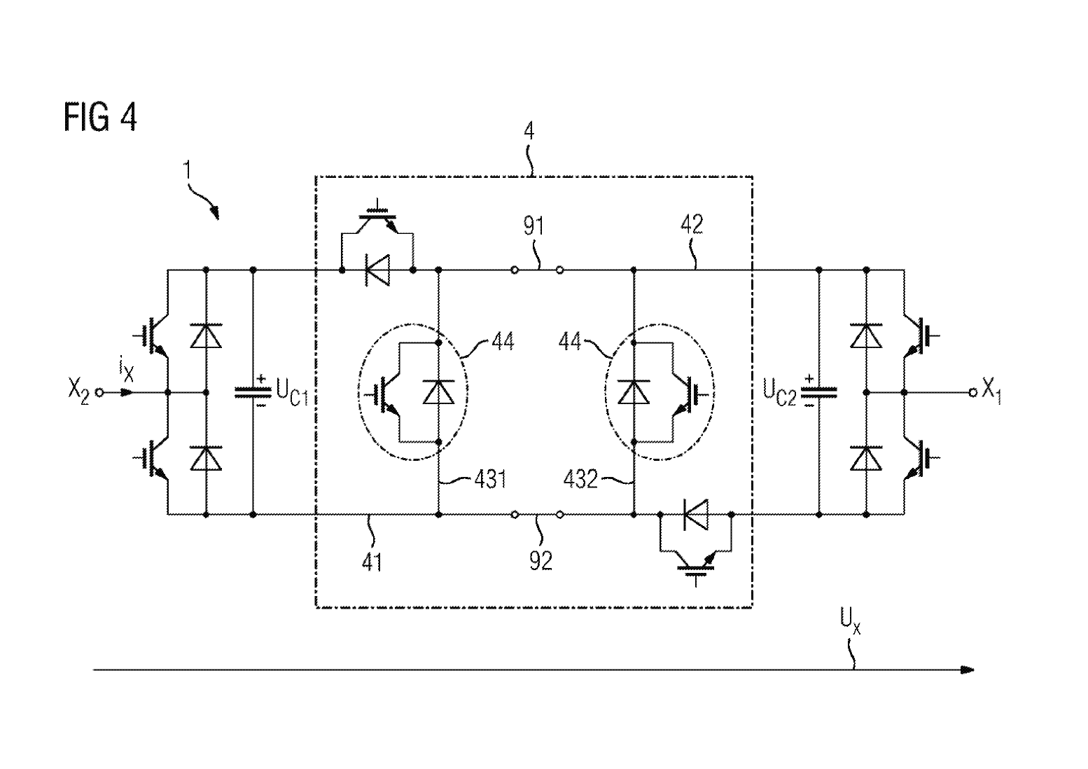

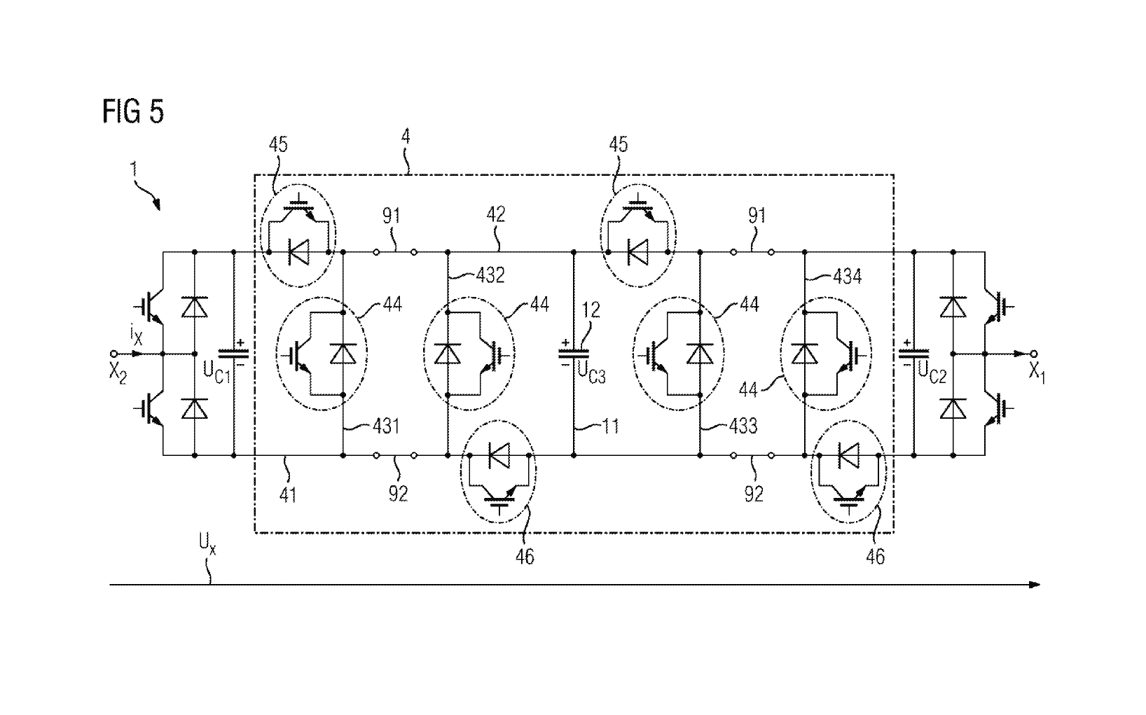

FIG. 4 shows a schematic representation of a second exemplary embodiment of the sub module according to the invention;

FIG. 5 shows a schematic representation of a third exemplary embodiment of the sub module according to the invention;

FIG. 6 shows a tabular summary of switching states of the sub module according to the invention.

In detail, FIG. 1 shows a converter 10, wherein the converter 10 is designed as a multi-stage converter. The converter 10 comprises three AC voltage terminals L1, L2, L3 for connecting to a three-phase AC voltage network. The converter 10 furthermore comprises DC voltage terminals 104, 105, 106, 107, 108 and 109 for connecting to a positive pole terminal 102 and a negative pole terminal 103.

The positive pole terminal 102 and the negative pole terminal 103 can be connected to a positive and negative pole respectively of a DC voltage network, not illustrated in FIG. 1.

The AC voltage terminals L1, L2, L3 can each be connected to a secondary winding of a transformer. The primary winding of the transformer is connected to an AC voltage network, not illustrated in FIG. 1. The direct electrical connection to the AC voltage network, for example with the intermediate connection of a coil or choke or of a capacitive component, is also possible in the context of the invention.

Power semiconductor valves 101 extend between each one of the DC voltage terminals 104, 105, 106, 107, 108, 109 and one of the AC voltage terminals L1, L2, L3. Each of the power semiconductor valves 101 comprises a series circuit of sub modules 1.

Each power semiconductor valve 101 moreover has a choke 5.

Each of the two-pole sub modules 1, which have identical designs in the embodiment illustrated in FIG. 1, comprises two current-carrying terminals X1 and X2.

In the exemplary embodiment illustrated in FIG. 1, the converter 10 is part of an HVDC installation, and serves to connect AC voltage networks via a high voltage direct current network. The converter 10 is constructed in order to transfer high electrical powers between the AC voltage networks. The converter 10 can, however, also be part of a reactive power compensation/network stabilization plant, such as for example what is known as a FACTS installation. Further applications of the converter 10, such as for example in drive technology, are moreover conceivable.

The basic structure of one embodiment of a sub module 1 according to the invention is illustrated in FIG. 3.

The sub module 1 comprises a first subunit 2 as well as a second subunit 3, each of which is indicated by a broken line for the purposes of illustration. The first subunit 2 and the second subunit 3 have the same structure.

The first subunit 2 comprises a first series circuit of power semiconductor switching units 22 and 23, which, in the variant embodiment shown, each comprise an IGBT 221 and 231 respectively as a power semiconductor that can be switched on and off, and in each case a freewheeling diode 222 and 232 respectively. The freewheeling diodes 222, 232 are connected in parallel but with opposite polarity with the respectively assigned IGBT 221, 231. The two IGBTs 221, 231 are oriented in the same sense as one another, and thus have the same forward conduction direction. The potential node between the power semiconductor switching units 22, 23 is connected to a first connecting terminal X2. The series circuit of the two power semiconductor switching units 22 and 23 is connected in parallel with a first energy store that is realized as a capacitor 21. A voltage UC1 is dropped across the capacitor 21.

The second subunit 3 comprises a first series circuit of power semiconductor switching units 32 and 33, which each comprise an IGBT 321 and 331 respectively as a power semiconductor that can be switched on and off, and in each case a freewheeling diode 322 and 332 respectively.

The freewheeling diodes 322, 332 are connected in parallel but with opposite polarity with the respectively assigned IGBT 321, 331. The two IGBTs 321, 331 are oriented in the same sense as one another, and thus have the same forward conduction direction. The potential node between the power semiconductor switching units 32, 33 is connected to a second connecting terminal X1. The series circuit of the two power semiconductor switching units 32 and 33 is connected in parallel with a first energy store that is realized as a capacitor 31. A voltage UC2 is dropped across the capacitor 31.

The subunits 2 and 3 are linked to one another via connecting means 4. The connecting means 4 are surrounded by a broken line in FIG. 3 for the purposes of illustration. The connecting means 4 comprise an emitter connecting branch 41 and a collector connecting branch 42.

The emitter connecting branch 41 connects an emitter of the IGBT 231 to an emitter of the IGBT 331. A power semiconductor switching unit 46 is arranged in the emitter connecting branch 41. The power semiconductor switching unit 46 comprises an IGBT 461 and a diode 462 connected in parallel with it but with the opposite polarity.

The collector connecting branch 42 connects a collector of the IGBT 221 to the collector of the IGBT 321. A power semiconductor switching unit 45 is arranged in the collector connecting branch 42. The power semiconductor switching unit 45 comprises an IGBT 451 and a diode 452 connected in parallel with it but with the opposite polarity.

The emitter connecting branch 41 is connected to the collector connecting branch 42 via a switching branch 43.

A switching unit is arranged in the switching branch 43 which, according to the exemplary embodiment illustrated in FIG. 3, is designed as a power semiconductor switching unit 44. The power semiconductor switching unit 44 comprises an IGBT 441 and a diode 442 connected in parallel with it but with the opposite polarity. The switching branch 43 connects the emitter of the IGBT 451 to the collector of the IGBT 461.

The manner in which the circuit of the sub module 1 according to the invention operates is to be explained in more detail below with reference to the table illustrated in FIG. 6; the table in FIG. 6 summarizes the switching states of the sub module 1 that are preferably used.

The first column of the table in FIG. 6 contains the serial number assigned to a switching state; the second column contains the information regarding the current direction/polarity of the terminal current ix; the third through ninth columns each reveal a state of the individual IGBTs, with the number 1 for “switched on” and 0 for “interrupting”, wherein each IGBT can be identified with reference to the associated numerical identifier from FIG. 3; the tenth column contains the terminal voltage UX associated with the respective switching state; columns WC1 and WC2 are to make clear whether the storage capacitors 21 and 31 are absorbing or releasing energy, wherein +1 represents the absorption and −1 represents the release of energy.

It can be seen from the table in FIG. 6 that a positive voltage UX is always generated at the connecting terminals X1 and X2 in switching states 2, 3 and 4. This is true regardless of the direction of the terminal current. Thus, for example, the capacitor voltage UC1 or the capacitor voltage UC2, or else the sum of the two capacitor voltages UC1+UC2, can be generated at the connecting terminals.

In switching state 5, all the IGBTs 231, 221, 331, 321, 441, 451, 461 are in their interrupting state, so that the flow of current through the IGBTs 231, 221, 331, 321, 441, 451, 461 is interrupted. In this switching state, the terminal voltage UX generates an opposing voltage, regardless of the polarity of the terminal current ix, so that the sub module 1 absorbs energy.

When the current direction is negative (current flowing in a direction opposite to the direction of the arrow identified by ix), an autonomous balancing of the capacitor voltages UC1 and UC2 means that, approximately, UX=−(UC1+UC2)/2. When the current direction is positive (current flowing in the direction of the arrow identified by ix), a positive opposing voltage UX=UC1+UC2 is developed. It is advantageous here that the current that occurs in this switching state is passed through both capacitors, since a lower over-voltage then occurs at them than if only one capacitor were to absorb the energy.

Switching state 5 can be used in the event of a fault for full current decay. If all the sub modules 1 are placed into this switching state, the branch currents of the converter 10, and consequently also the currents on the AC voltage side and the DC voltage side, are brought down to a value of zero very quickly as a result of the total of the opposing voltages of all the series-connected sub modules 1. The speed of this current decay results from the above-mentioned opposing voltage and from the total inductances present in the electric circuits. In the case of the illustrated exemplary embodiment, this can typically lie in the order of magnitude of a few milliseconds. The dead time before the current decay starts depends largely on the response time of the switching unit 44. If a power semiconductor switching unit is used for the switching unit 44, this dead time is negligible. The dead time is then primarily a result of the slowness of the various measuring sensors and current converters with whose aid a fault is recognized. This delay in this measurement value acquisition is at present typically in the range of a few tens of microseconds.

It should be noted that the first four switching states can also be realized using two cascaded sub modules from the prior art according to FIG. 2. The first five of the switching states can be realized using the sub module designed according to document DE 10 2009 057 288 A1.

In switching state 6, a negative terminal voltage UX of the sub module 1 is generated whatever the current direction.

In switching state 7, a negative terminal voltage UX of the sub module 1 is also generated whatever the current direction.

Additional (redundant) switching states 8 and 9 are moreover possible, which can be used for a more even distribution of the conduction losses when UX=0.

FIG. 4 illustrates a second exemplary embodiment of the sub module 1 according to the invention. Parts in FIGS. 3, 4 and 5 that are identical and equivalent are here given the same reference signs in each case. For the avoidance of repetitions, only the differences between the individual embodiments will therefore be considered in more detail below.

The sub module 1 according to FIG. 4 differs from the embodiment of FIG. 3 in that the connecting means 4 in FIG. 4 comprise two switching branches 431 and 432. Each of the switching branches comprises a power semiconductor switching unit 44.

Connecting lines 91 and 92 are arranged between the switching branches 431 and 432 as parts of the emitter and collector connecting branch 41, 42 respectively. The particular advantage of the embodiment of FIG. 4 is that the length and the stray inductance of the connecting lines 91, 92 are not critical for the overall performance of the sub module 1. The connecting lines can thus have a length that is adapted to the particular application. A structurally and spatially separate or adapted construction of the sub module 1 can be of great advantage for production and for servicing.

FIG. 5 shows a schematic representation of a third embodiment of the sub module 1 according to the invention. The emitter connecting branch of the connecting means 4 here comprises two connecting lines 92 as well as two power semiconductor switching units 45. The collector connecting branch 42 of the connecting means 4 also comprises two connecting lines 91 as well as two power semiconductor switching units 46.

The connecting means 4 furthermore comprise four switching branches 431, 432, 433 and 434, wherein a power semiconductor switching unit 44 is arranged in each switching branch. The connecting means 4 furthermore comprise an energy storage branch 11 in which a third energy store 12 is arranged which, in the present example, is designed as a unipolar storage capacitor, across which the voltage UC3 is dropped.

### TABLE OF REFERENCE SIGNS

1 Sub module
2 First subunit
21 First energy store
22, 23 Power semiconductor switching unit
221, 231 Power semiconductor
222, 232 Freewheeling diode
3 Second subunit
31 Second energy store
32, 33 Power semiconductor switching unit
321, 331 Power semiconductor
322, 332 Freewheeling diode
4 Connecting means
41 Emitter connecting branch
42 Collector connecting branch
43, 431, 432 Switching branch
433, 434 Switching branch
44 Switching unit
45, 46 Power semiconductor switching unit
441, 451, 461 Power semiconductor
442, 452, 462 Freewheeling diode
5 Choke
6 Energy store
7 Power semiconductor switching unit
71, 72 Freewheeling diode
73, 74 Electronic switch
8 Thyristor
91, 92 Connecting line
10 Converter
101 Power semiconductor valve
102 Positive pole terminal
103 Negative pole terminal
104, 105, 106 DC voltage terminal
107, 108, 109 DC voltage terminal
11 Energy storage branch
12 Third energy store
L1, L2, L3 AC voltage terminal
X1 Second connecting terminal
X2 First connecting terminal

1-10. (canceled)

11. A sub module for constructing a converter, the submodule comprising:
a first subunit having:
a first energy storage device;
a first series circuit connected in parallel with said first energy storage device, said first series circuit having two power semiconductor switching units, each including a power semiconductor that can be switched on and off and having the same forward conduction directions, and each configured to conduct in a direction opposite to the forward conduction direction; and
a first connecting terminal connected to a potential node between said power semiconductor switching units of said first series circuit; and
a second subunit having:
a second energy storage device;
a second series circuit connected in parallel with said second energy storage device, said second series circuit having two power semiconductor switching units, each including a power semiconductor that can be switched on and off and having the same forward conduction directions, and each configured to conduct in a direction opposite to the forward conduction direction; and
a second connecting terminal connected to a potential node between said power semiconductor switching units of said second series circuit;
a connection device connecting said first subunit and said second subunit to one another, said connection device including:
an emitter connecting branch that connects an emitter of a first said power semiconductor switching unit of said first series circuit to an emitter of a first power semiconductor switching unit of said second series circuit;
a collector connecting branch that connects a collector of a second power semiconductor switching unit of said first series circuit to a collector of a second power semiconductor switching unit of said second series circuit; and
a switching branch with a switching unit arranged therein connecting said emitter connecting branch to said collector connecting branch; and
at least one power semiconductor switching unit connected in said emitter connecting branch or in said collector connecting branch.

12. The sub module according to claim 11, wherein said at least one power semiconductor switching unit includes at least one power semiconductor switching unit connected in said emitter connecting branch and at least one power semiconductor switching unit connected in said collector connecting branch.

13. The sub module according to claim 12, wherein said switching branch connects an emitter of said power semiconductor switching unit in said collector connecting branch to a collector of said power semiconductor switching unit in said emitter connecting branch.

14. The sub module according to claim 11, wherein said switching unit is a device selected from the group consisting of a mechanical switching unit, a semiconductor switch and a power semiconductor switching unit.

15. The sub module according to claim 11, wherein, in a switching state of the sub module in which all said power semiconductor switching units are in an interrupting state, the sub module is configured to absorb energy regardless of a current direction.

16. The sub module according to claim 11, wherein said power semiconductor switching units are reverse-conducting power semiconductor switches that can be switched on and off.

17. The sub module according to claim 11, wherein each said power semiconductor switching unit comprises a power semiconductor that can be switched on and off, and a freewheeling diode connected in parallel but with opposite polarity.

18. The sub module according to claim 11, wherein each energy storage device is a unipolar storage capacitor.

19. The sub module according to claim 11, wherein said connection device includes a second switching branch connecting said emitter switching branch to said collector switching branch, and having a power semiconductor switching unit arranged therein.

20. A converter, comprising:
an AC voltage terminal and a DC voltage terminal; and
a series circuit of a plurality of two-pole sub modules each according to claim 11, said series circuit of said sub modules being connected between said AC voltage terminal and said DC voltage terminal of the converter.
